(19) United States
(12) Patent Application Publication
(10) Pub. No.: US 2021/0057292 A1
(43) Pub. Date: Feb. 25, 2021

(54) METHODS AND APPARATUS FOR DETERMINING ENDPOINTS FOR CHEMICAL MECHANICAL PLANARIZATION IN WAFER-LEVEL PACKAGING APPLICATIONS

(71) Applicant: APPLIED MATERIALS, INC., Santa Clara, CA (US)

(72) Inventors: PRAYUDI LIANTO, SINGAPORE (SG); SHIH-CHAO HUNG, SINGAPORE (SG); GEOK SAN TOH, SINGAPORE (SG)

(21) Appl. No.: 16/545,997

(22) Filed: Aug. 20, 2019

(51) Int. Cl. H01L 21/66; H01L 21/56; H01L 21/3105; H01L 23/00

(52) U.S. Cl. CPC H01L 22/26; H01L 21/561; H01L 21/31053; H01L 2224/03616; H01L 24/11; H01L 2224/0231; H01L 2224/11616; H01L 24/03

(57) ABSTRACT

Methods and apparatus for chemical mechanical planarization (CMP) of a polymer or epoxy-based layer. In some embodiments, the method may comprise obtaining an endpoint for polymer or epoxy-based material for use in a CMP process, the CMP process configured to polish polymer or epoxy-based material, monitoring the polymer or epoxy-based layer with an endpoint detection apparatus configured to monitor polymer or epoxy-based material, polishing the polymer or epoxy-based layer with the CMP process, detecting when the polymer or epoxy-based layer has reached the endpoint for the CMP process, and halting the CMP process when the endpoint is detected. The endpoint detection apparatus may further comprise an optical detection apparatus configured to operate at a wavelength of approximately 200 nm to approximately 1700 nm to reduce step height of the polymer or epoxy-based layer.

### FIELD

Embodiments of the present principles generally relate to semiconductor processes used in packaging semiconductor devices.

### BACKGROUND

Advanced packaging has paved the way to produce semiconductor chip packages with improved performance for various applications, such as mobile communications, computing, and internet of things (IoT). To achieve this, wafer-level processing is no longer limited to standard silicon wafers, but also covers reconstituted wafers. The latter refers to the case where chips from different wafers may be combined together by placing the chips on a surface and overlaying the chips with a polymer material, typically epoxy mold compound (EMC). The chips often contain complex circuitry which needs to interact with external components. Lead outs are formed that are connected to the internal circuitry of the chip to a pad or solder ball that allows for external connections. Common building blocks to achieve the connection are through-silicon vias (TSV), Cu pillars (bumps), and redistribution layers (RDLs). In the case of RDLs, for example, as the technology node keeps scaling down, non-uniformities in the surface of the polymer layer, such as those caused by the embedded chips, limit the spacing of the connections. The inventors have found that the non-uniformities necessitate the use of chemical mechanical planarization (CMP) in the wafer-level process flow. In another example, one may use thick RDL or bump which requires a thick polymer or an EMC encapsulation layer. In the example, not only is a fast removal process required, but also the introduction of a heterogeneous material like EMC (epoxy filled with silica fillers) may present a new challenge in monitoring the thickness of the EMC material.

Thus, the inventors have provided an improved method and apparatus for reducing non-uniformities in the surface of the substrate.

### SUMMARY

Methods and apparatus for reducing non-uniformities of a surface of a substrate are provided herein.

In some embodiments, a method for chemical mechanical planarization (CMP) of a polymer or epoxy-based layer may comprise obtaining an endpoint for polymer or epoxy-based material for use in a CMP process, the CMP process configured to polish polymer or epoxy-based material; monitoring the polymer or epoxy-based layer with an endpoint detection apparatus configured to monitor polymer or epoxy-based material, polishing the polymer or epoxy-based layer with the CMP process; detecting when the polymer or epoxy-based layer has reached the endpoint for the CMP process; and halting the CMP process when the endpoint is detected.

In some embodiments, the method may further comprise using an optical detection apparatus as the endpoint detection apparatus, the optical detection apparatus is configured to operate at a wavelength of approximately 200 nm to approximately 1700 nm and is configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm, using an optical detection apparatus as the endpoint detection apparatus, wherein the polymer or epoxy-based layer has at least one underlying redistribution layer or bump and the optical detection apparatus is configured to operate at a wavelength of approximately 200 nm to approximately 1700 nm and to planarize the polymer or epoxy-based layer; obtaining the endpoint for the polymer or epoxy-based layer from a combination of stored data and monitored data; using an optical detection apparatus as the endpoint detection apparatus, the optical detection apparatus is configured to operate at a wavelength of approximately 200 nm to approximately 1700 nm and is configured to detect a reveal of a metal-based material in the polymer or epoxy-based layer; using a laser detection apparatus as the endpoint detection apparatus, the laser detection apparatus is configured to detect metal clearance in a polymer damascene structure in the polymer or epoxy-based layer; using a motor torque detection apparatus as the endpoint detection apparatus, the motor torque detection apparatus is configured to detect metal reveals in the polymer or epoxy-based layer based on changes in torque applied to one or more motors of a CMP process chamber; using an eddy current detection apparatus as the endpoint detection apparatus, the eddy current detection apparatus is configured to detect a thickness of a metal-based material in the polymer or epoxy-based layer; using an X-ray detection apparatus as the endpoint detection apparatus, the X-ray detection apparatus is configured to non-destructively detect a thickness of the polymer or epoxy-based layer; and/or using more than one of an optical detection apparatus, a motor torque detection apparatus, an eddy current detection apparatus, and an X-ray detection apparatus as the endpoint detection apparatus.

In some embodiments, a method for chemical mechanical planarization (CMP) of a polymer or epoxy-based layer may comprise obtaining an endpoint for polymer or epoxy-based material for use in a CMP process, the CMP process configured to polish polymer or epoxy-based material, monitoring the polymer or epoxy-based layer with an optical detection apparatus configured to monitor polymer or epoxy-based material and configured to operate at a wavelength of approximately 200 nm to approximately 800 nm or a wavelength of approximately 900 nm to approximately 1700 nm, polishing the polymer or epoxy-based layer with the CMP process, detecting when the polymer or epoxy-based layer has reached the endpoint for the CMP process, and halting the CMP process when the endpoint is detected.

In some embodiments, the method may further comprise wherein the optical detection apparatus is configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm; wherein the polymer or epoxy-based layer has at least one underlying redistribution layer or bump and the optical detection apparatus is configured to planarize polymer or epoxy-based layer; obtaining the endpoint for the polymer or epoxy-based layer from a combination of stored data and monitored data; wherein the optical detection apparatus is configured to detect a reveal of a metal-based material in the polymer or epoxy-based layer; and/or using the optical detection apparatus and at least one of a motor torque detection apparatus, an eddy current detection apparatus, and an X-ray detection apparatus to detect the endpoint of the CMP process for the polymer or epoxy-based layer.

In some embodiments, a non-transitory, computer readable medium having instructions stored thereon that, when executed, cause a method for chemical mechanical planarization (CMP) of a polymer or epoxy-based layer to be performed, the method comprising obtaining an endpoint for polymer or epoxy-based material for use in a CMP process, the CMP process configured to polish polymer or epoxy-based material, monitoring the polymer or epoxy-based layer with an endpoint detection apparatus configured to monitor polymer or epoxy-based material, polishing the polymer or epoxy-based layer with the CMP process, detecting when the polymer or epoxy-based layer has reached the endpoint for the CMP process, and halting the CMP process when the endpoint is detected.

In some embodiments, method of the non-transitory, computer readable medium of may further comprise using an optical detection apparatus as the endpoint detection apparatus, the optical detection apparatus is configured to operate at a wavelength of approximately 200 nm to approximately 1700 nm and configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm, using an optical detection apparatus as the endpoint detection apparatus, the optical detection apparatus is configured to operate at a wavelength of approximately 200 nm to approximately 1700 nm and configured to detect a reveal of a metal-based material in the polymer or epoxy-based layer, and/or using more than one of an optical detection apparatus, a motor torque detection apparatus, an eddy current detection apparatus, and an X-ray detection apparatus as the endpoint detection apparatus.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross sectional view of a chemical mechanical planarization (CMP) apparatus in accordance with some embodiments of the present principles.

FIG. 2 is a method of planarization a polymer-based layer in accordance with some embodiments of the present principles.

FIG. 3 depicts a cross sectional view of a substrate with a polymer-based layer in accordance with some embodiments of the present principles.

FIG. 4A depicts a cross sectional view of an in-film endpoint detection process of a polymer-based layer in accordance with some embodiments of the present principles.

FIG. 4B depicts a cross sectional view of a substrate with a polymer-based layer with underlying metallization in accordance with some embodiments of the present principles.

FIG. 5A depicts a cross sectional view of a reveal endpoint detection process of a polymer-based layer in accordance with some embodiments of the present principles.

FIG. 5B depicts a cross sectional view of a damascene structure in accordance with some embodiments of the present principles.

FIG. 6 depicts a cross sectional view of an endpoint detection process for a damascene structure in a polymer-based layer in accordance with some embodiments of the present principles.

FIG. 7 depicts a cross sectional view of an endpoint detection process using X-rays in a polymer-based layer in accordance with some embodiments of the present principles.

FIG. 8 depicts a cross sectional view of an endpoint detection process using an eddy current in a polymer-based layer in accordance with some embodiments of the present principles.

FIG. 9 depicts a graph of an endpoint detection process using motor torque in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

A chemical mechanical planarization (CMP) process is used to enable fine pitch patterning of a polymer-based redistribution layer (RDL) for wafer level packaging. The fine pitch patterning is accomplished by planarizing or polishing a surface of a polymer-based layer on a substrate using CMP endpoints for polymer-based materials. The inventors discovered that polymer-based materials provide a higher level of uniformity after a CMP process, allowing for very close spacing of circuit interconnects, such as line and spacing of greater than 0/0 μm to approximately 2/2 μm or less. In current processes, the new polymer-based material may be polished based on timing and inspection. Timing-based polishing typically wastes material due to extra thicknesses used to prevent burn through of the polymer-based layer when using timing to polish the polymer-based layer. In addition, timing based polishing is subject to slurry removal rate stability. The slurry used in the CMP process may not have a linear removal rate, causing an unknown amount of material to be removed during the timed process. The inventors have discovered several CMP endpoint methods and apparatus that may be utilized to control the polishing of polymer or epoxy-based materials in place of time-based polishing, solving the lack of CMP endpoint systems available for the new class of polymer-based materials which include epoxy-based materials.

The methods and apparatus of the present principles allow thinner polymer layers to be used, allow an increase in the patterning resolution window, and allow control of dishing to improve bonding performance of polymer-based materials, lowering processing costs. In some embodiments, the methods and apparatus may include endpoint determination based on optical systems that operate over a broadband (approximately 200 nm to approximately 1700 nm) for polymer or epoxy thickness and step height control. In some embodiments, the methods and apparatus may include endpoint determination based on lasers for metal clearance in polymer damascene structures. In some embodiments, the methods and apparatus may include endpoint determination based on motor torque control for copper or other metal reveals. In some embodiments, the methods and apparatus may include endpoint determination based on eddy current for metal thickness control in hybrid bonding applications. In some embodiments, the methods and apparatus may include endpoint determination based on electromagnetics (X-rays) for thick absorbing material such as epoxy molding compound (EMC). In some embodiments, multiple types of endpoint determination may be combined together to yield enhanced results.

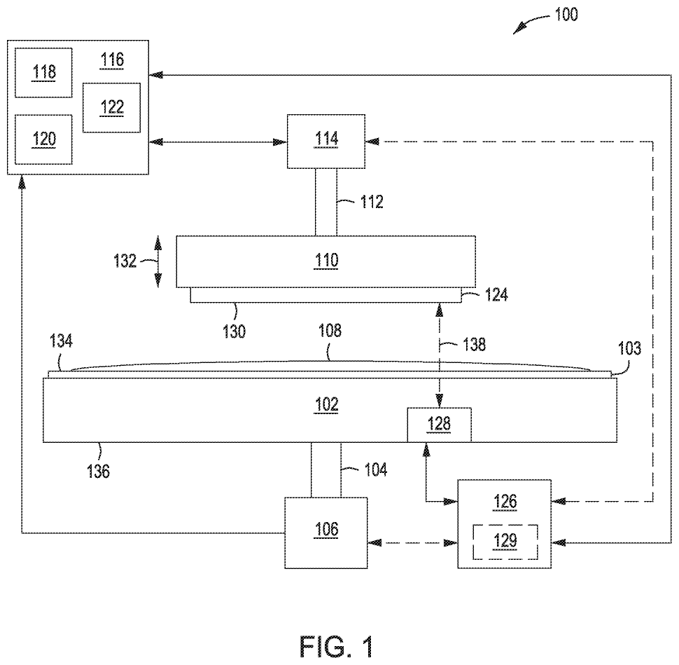

FIG. 1 is a cross sectional view of a chemical mechanical planarization (CMP) apparatus 100 in accordance with some embodiments. The CMP apparatus 100 includes a rotatable platen 102 and a platen motor 106 that transfers rotational energy to the rotatable platen 102 via a platen drive transfer apparatus 104. The platen drive transfer apparatus 104 may directly (e.g., via a drive shaft or rod, etc.) or indirectly (e.g., via a belt, a chain, etc.) transfer rotational energy to the rotatable platen 102 from the platen motor 106. The rotatable platen 102 is covered with a polishing pad 103 which can either be a standard pad or a fixed-abrasive pad. A standard pad has a roughened surface with a specific wear-out lifetime, while a fixed-abrasive pad contains embedded abrasive particles. During CMP processes, a slurry 108 for polymer-based materials is used on the polishing pad 103 to enhance the polishing of the polymer-based material on the substrate 124. The CMP apparatus 100 also includes a carrier head 110 which holds a substrate 124 during a polishing process. The carrier head 110 may be moved up and down (arrow 132) such that a surface 130 of the substrate 124 may come into contact with a top surface 134 of the polishing pad 103 for polishing of the surface 130 of the substrate 124. The carrier head 110 is rotated by a carrier head motor 114 that provides rotational energy to the carrier head 110 via carrier head drive transfer apparatus 112. The carrier head drive transfer apparatus 112 may directly (e.g., via a drive shaft or rod, etc.) or indirectly (e.g., via a belt, a chain, etc.) transfer rotational energy to the carrier head 110 from the carrier head motor 114.

The CMP apparatus 100 also includes a system controller 116. The system controller 116 controls the operation of the CMP apparatus 100 directly and/or indirectly by controlling other computers (or other controllers) associated with other subsystems of the CMP apparatus 100. In operation, the system controller 116 enables data collection and feedback from the subsystems to optimize performance of the CMP apparatus 100. The system controller 116 generally includes a central processing unit (CPU) 118, a memory 120, and a support circuit 122. The CPU 118 may be any form of a general purpose computer processor that can be used in an industrial setting. The support circuit 122 is conventionally coupled to the CPU 118 and may comprise a cache, clock circuits, input/output subsystems, power supplies, and the like. Software routines, such as the methods described below may be stored in the memory 120 or other computer readable media and, when executed by the CPU 118, transform the CPU 118 into a specific purpose computer (system controller 116). The software routines may also be stored and/or executed by a second controller (not shown) that is located remotely from the CMP apparatus 100. The memory 120 may also be utilized to store data for use with CMP processes associated with endpoints for polymer-based material planarization.

The CMP apparatus 100 may also include a polymer endpoint detection apparatus 126 that includes and is in communication with a polymer endpoint detector 128. In some embodiments, the polymer endpoint detector 128 may be embedded in the rotatable platen 102 near a bottom surface 136 of the rotatable platen 102 (shown), embedded in a center portion of the rotatable platen 102 approximately midway between the top surface 134 and the bottom surface 136, embedded near a top surface 134 of the rotatable platen 102, and/or positioned below the rotatable platen 102. The polymer endpoint detector 128 interacts 138 with the substrate 124 during planarization to obtain parameters associated with a polymer or epoxy-based layer on the substrate 124. In some embodiments, the polymer endpoint detector 128 may include transmitters and receivers to assist in obtaining parameters during CMP processes. In some embodiments, the polymer endpoint detection apparatus 126 may interact with the platen motor 106 and/or the carrier head motor 114 to detect torque parameters during the CMP process. In some embodiments, the polymer endpoint detector 128 may include apparatus for detecting eddy currents in the substrate 124. In some embodiments, the polymer endpoint detection apparatus 126 may be positioned with the polymer endpoint detector 128, may be positioned separate from the polymer endpoint detector 128 (shown), and/or may be part of the system controller 116.

The polymer endpoint detection apparatus 126 processes data relating to polymer or epoxy-based materials to determine endpoints for the CMP processing of the substrate 124. Polymer and epoxy (e.g., EMC) have a higher absorption rate and lower reflection intensity than other dielectrics. The polymer endpoint detection apparatus 126 may alter the transmitter and receiver parameters (e.g., transmission power, receiver sensitivity, transmission signal wavelength, etc.) of the polymer endpoint detector 128 to optimize results obtained by the polymer endpoint detector 128 for the polymer-based material on the substrate 124. The polymer endpoint detection apparatus 126 may also adjust detection parameters and/or polymer CMP endpoints based on the composition of the polymer-based material on the substrate 124 and/or the type of CMP process to be accomplished. Some polymer-based layers on the substrate 124 may contain chip die and/or metallic structures (e.g., vias, contact pads, etc.) that may be revealed (exposed) during the CMP process. Other CMP processes may have hidden or in-film structures that are to remain overlaid with polymer material and are not to be exposed during the CMP process. The process purpose, composition of the polymer-based layer, stored historical data for a given CMP process (e.g., removal rates, variations, etc.), and/or absorption rate of transmitted signals used by the polymer endpoint detector 128 may affect the determination of the polymer CMP endpoint by the polymer endpoint detection apparatus 126.

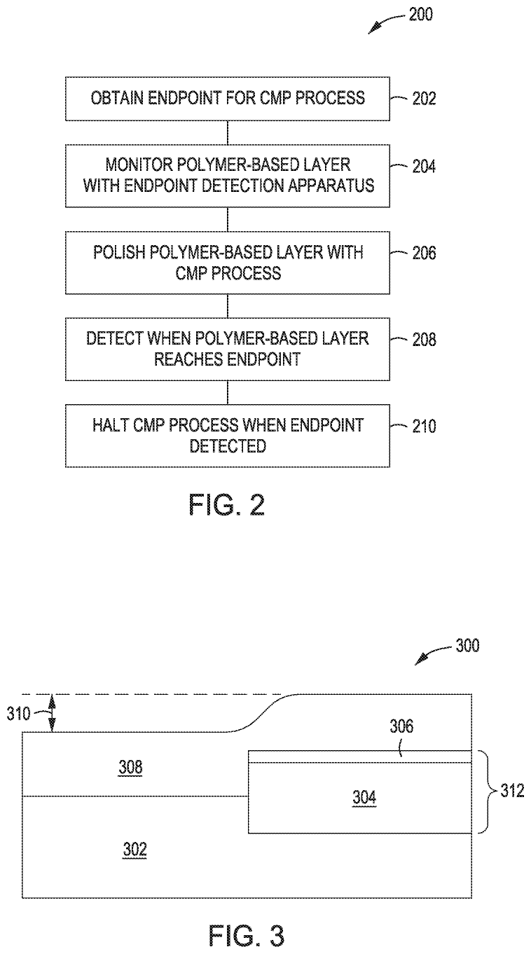

FIG. 2 is a method 200 of planarizing or polishing a polymer-based layer on the substrate 124 in accordance with some embodiments. In block 202, a CMP endpoint for polymer-based material is obtained for use in a CMP process that planarizes or polishes the polymer-based layer. In some embodiments, the CMP endpoint may be determined based on stored information such as historical polymer polishing data, determined based on the composition of the polymer-based layer on the substrate 124 (e.g., polymer properties, absorption rate, presence of chip dies or metallic structures, and/or determined based on type of CMP process (e.g., revealing of sub-structures in the polymer-based layer, leaving sub-structures concealed, etc.). In block 204, the polymer-based layer is monitored by the polymer endpoint detection apparatus 126 (including the polymer endpoint detector 128). The polymer endpoint detection apparatus 126 may utilize optical detection processes (including near infrared and/or lasers), motor torque detection processes, eddy current detection processes, and/or X-ray based detection processes to monitor and detect CMP endpoints during the CMP processing. In block 206, the polymer-based layer on the substrate 124 is polished or planarized with a CMP process for polymer materials. In block 208, detection of an endpoint of the CMP process occurs by the polymer endpoint detection apparatus 126. The endpoint detection may be based on a direct parameter value being met and/or detection parameters may be used to compare to historical data to determine that an endpoint has been reached. In block 210, the CMP process is halted when the endpoint has been reached.

In FIG. 3, a cross sectional view 300 of a substrate 302 with a polymer-based layer 308 in accordance with some embodiments is shown. In the example, the substrate 302 is composed of epoxy mold compound (EMC) with an embedded chip die 312 including a silicon base 304 and an aluminum layer 306. When polymer is formed on the substrate 302 and embedded chip die 312, a step-height 310 occurs where the polymer overlays the embedded chip die 312. The difference in height on the surface of the substrate 302 precludes formation of fine pitch RDLs. CMP processes according to the present principles reduce the step-height 310 to allow the polymer-based layer 308 to achieve a surface uniformity that supports fine pitch RDLs. In some embodiments, a redistribution layer may be formed after CMP processing with at least two lead outs with line and spacing of approximately greater than 0/0 μm to less than or equal to approximately 2/2 μm.

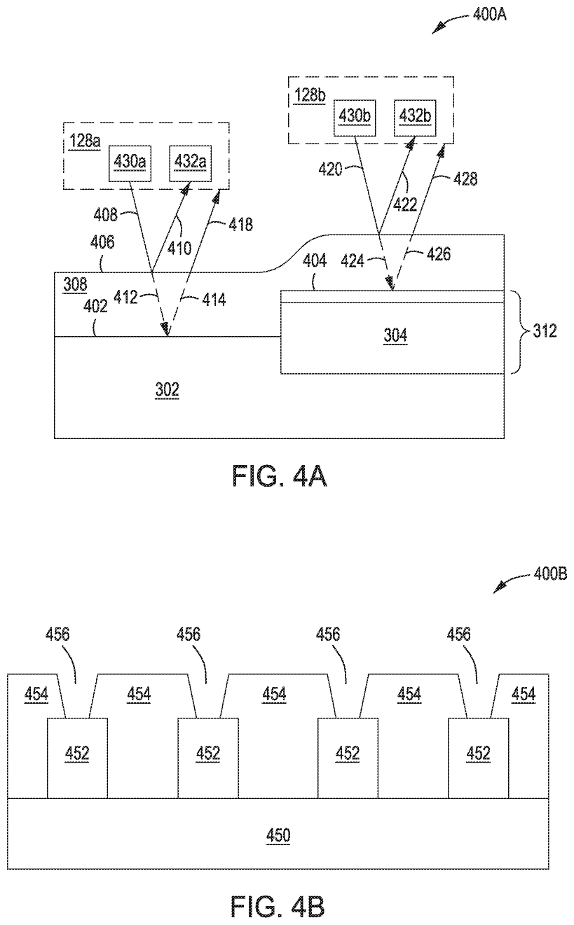

FIG. 4A depicts a cross sectional view 400A of an in-film endpoint detection process of the polymer-based layer 308 in accordance with some embodiments. In some embodiments, the polymer endpoint detection apparatus 126 uses an optical light transmitter 430a, 430b and an optical light receiver 432a, 432b in the polymer endpoint detector 128 (128a, 128b) that operates at a wavelength of approximately 200 nm to approximately 1700 nm to detect an endpoint in order to reduce the step-height 310 of the polymer-based layer 308. In some embodiments, the polymer endpoint detector 128 operate at a wavelength of approximately 200 nm to approximately 800 nm or a wavelength of approximately 900 nm to approximately 1700 nm.

In a first scenario, the polymer endpoint detector 128a transmits an optical light beam 408 at a surface 406 of the polymer-based layer 308 at a location without an embedded chip die. A first portion 410 of the optical light beam 408 is reflected back to the optical light receiver 432a. A second portion 412 penetrates through the polymer-based layer 308 and reflects off of a surface 402 of the EMC of the substrate 302 as a third portion 414 of the optical light beam 408 that penetrates back through the polymer-based layer 308 and to the optical receiver 432a as a fourth portion 418. The inventors found that the polymer-based layer 308 and the EMC of the substrate 302 have different absorption and reflective properties than other dielectrics. For the case of thick polymer, the power and intensity of the optical light transmitter 430a may be increased so that the optical light beam 408 can penetrate the polymer-based layer 308 and to compensate for the absorbing property of the polymer and/or reduced reflective properties of the EMC. The sensitivity of the optical light receiver 432a may also be adjusted to account for the difference in reflective properties of the polymer-based layer 308 and the EMC of the substrate 302. In the first scenario, the polymer endpoint detection apparatus 126 may include compensation for the differences in the absorption and/or reflective properties. The compensation may include referencing historical information to assist in determining if an endpoint has been reached.

In a second scenario, the polymer endpoint detector 128b transmits an optical light beam 420 at a surface 406 of the polymer-based layer 308 at a location that includes an embedded chip die. A first portion 422 of the optical light beam 420 is reflected back to the optical light receiver 432b. A second portion 424 penetrates through the polymer-based layer 308 and reflects off of a surface 404 of the embedded chip die 312 in the substrate 302 as a third portion 426 of the optical light beam 420 that penetrates back through the polymer-based layer 308 and to the optical receiver 432b as a fourth portion 428. In the example, the reflected intensity power is sufficiently high to be processed by the polymer endpoint detector 128b and processed by the polymer endpoint detection apparatus 126. For the case of thick polymer or epoxy (EMC), power and intensity of the optical light transmitter 430b may still need to be increased. The inventors have found that the same endpoint technique can be generalized to endpoint polymer CMP with underlying metallization (e.g., RDL or bump), as shown in FIG. 4B. The inventors also found that if a ratio of reflective surfaces (metallization) to non-reflective surfaces (e.g., polymer or epoxy, etc.) is appreciable (e.g., reflective density is greater than approximately 10%), the optical endpoint apparatus may have reduced transmission power and/or reception sensitivity demands. The metallization can be the first, second, or n^{th} RDL, or Cu pillar/bump and the substrate can be standard silicon (Si) or glass. In FIG. 4B, a cross sectional view 400B is shown of a substrate 450 with a polymer-based layer 454 with underlying metallization 452 (e.g., RDL or bump, etc.). Vias 456 have been formed in the polymer-based layer 454 to provide electrical connections to the underlying metallization 452. In the example, the planarization of the polymer-based layer 454 by the CMP process stops at an endpoint within the polymer-based layer 454 without fully revealing the metallization 452 so that the vias 456 are preserved in the polymer-based layer 454.

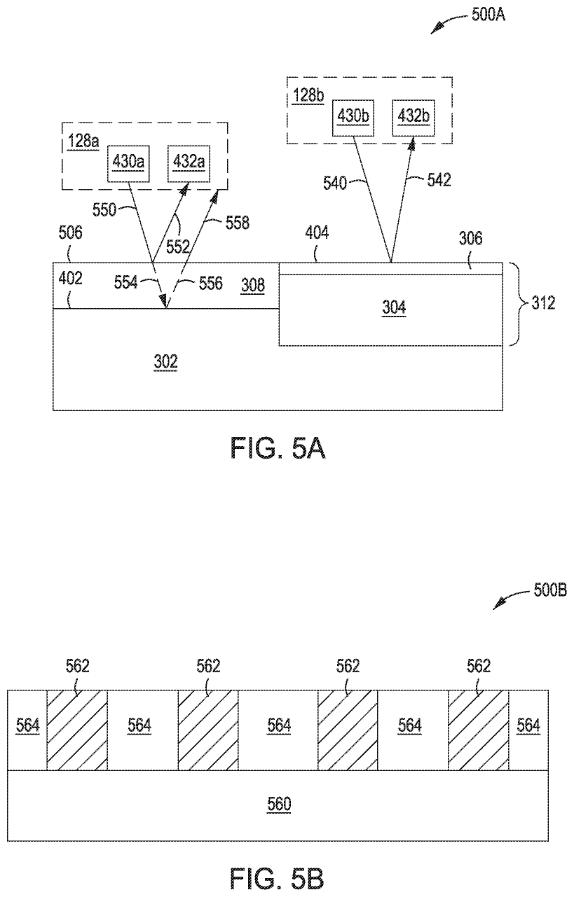

FIG. 5 depicts a cross sectional view 500 of a reveal endpoint detection process of a polymer-based layer in accordance with some embodiments. In some embodiments, the polymer endpoint detection apparatus 126 uses an optical light transmitter 430a, 430b and an optical light receiver 432a, 432b in the polymer endpoint detector 128 (128a, 128b) that operates at a wavelength of approximately 200 nm to approximately 1700 nm to detect an endpoint in order to reveal an underlying structure such as the embedded chip die 312. In a first scenario, the polymer endpoint detector 128a transmits an optical light beam 550 at a surface 506 of the polymer-based layer 308 at a location without an embedded chip die. A first portion 552 of the optical light beam 550 is reflected back to the optical light receiver 432a. A second portion 554 penetrates through the polymer-based layer 308 and reflects off of the surface 402 of the EMC of the substrate 302 as a third portion 556 of the optical light beam 550 that penetrates back through the polymer-based layer 308 and to the optical receiver 432a as a fourth portion 558. The inventors found that the polymer-based layer 308 and the EMC of the substrate 302 have different absorption and reflective properties than other dielectrics. For the case of thick polymer, the power and intensity of the optical light transmitter 430a may be increased so that the optical light beam 550 can penetrate the polymer-based layer 308 and to compensate for the absorbing property of the polymer and/or reduced reflective properties of the EMC. The sensitivity of the optical light receiver 432a may also be adjusted to account for the difference in reflective properties of the polymer-based layer and the EMC of the substrate 302. In the first scenario, the polymer endpoint detection apparatus 126 may include compensation for the differences in the absorption and/or reflective properties. The compensation may include referencing historical information to assist in determining if an endpoint (e.g., reveal of the embedded chip die 312) has been reached based on a thickness of the polymer-based layer 308. In a second scenario, the polymer endpoint detector 128b transmits an optical light beam 540 at a surface of the polymer-based layer 308 at a location that includes the surface 404 of the embedded chip die 312. Because the embedded chip die 312 is metallic (e.g., aluminum layer 306), a reflected portion 542 of optical light beam 540 is approximately equal to the optical light beam 440 when the embedded chip die 312 is revealed. In some embodiments, the polymer endpoint detection apparatus 126 may utilize the high reflection intensity to determine that a reveal has occurred and that an endpoint is reached, halting the CMP process. The inventors found that the same endpoint technique can be generalized to perform reveal endpoint detection on copper features (e.g., RDL or bump) embedded in polymer/EMC matrix, as shown in FIG. 5B. The metallization can be the first, second, or n^{th} RDL, or Cu pillar/bump and the substrate can be standard Si or glass. In FIG. 5B, a cross sectional view 500B is shown of a substrate 560 with a polymer-based layer 564 with revealed metallization 562 (e.g., RDL or bump, etc.). The CMP process has planarized the polymer-based layer 564 until the metallization 562 is exposed using a polymer-based endpoint detection for reveals.

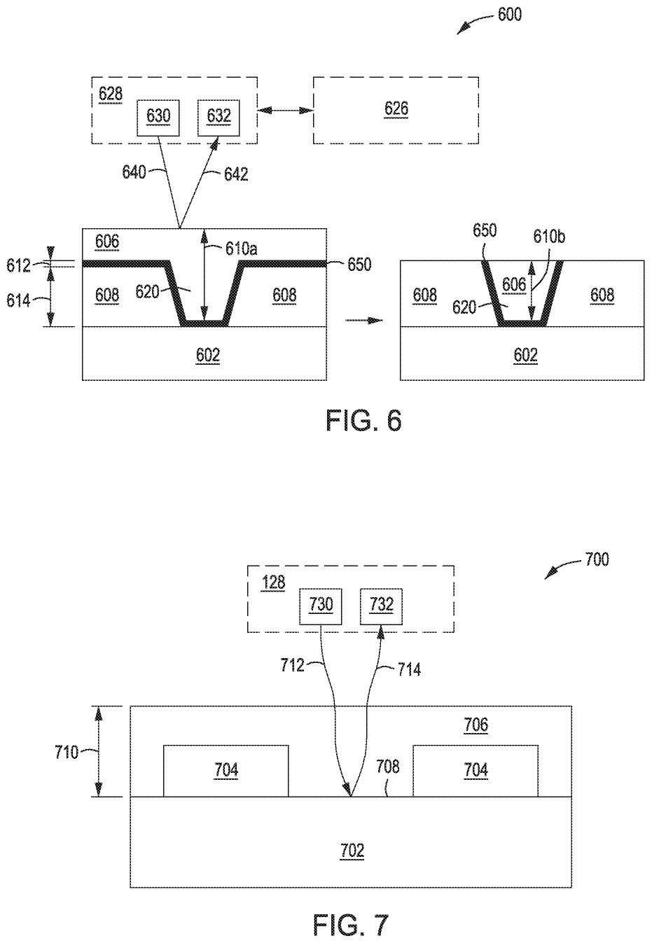

In FIG. 6, a cross sectional view 600 of an endpoint detection process for a damascene structure 620 on a polymer-based layer 608 with a thickness 614 on a substrate 602 in accordance with some embodiments. The damascene structure 620 is formed from a copper material with a first thickness 610a and a titanium lining 650 (e.g., titanium nitride barrier layer, etc.) with a thickness 612. In some embodiments, an endpoint detection apparatus 626 uses an endpoint detector 628 that includes transmitter 630 with a laser that produces a coherent light beam 640. The endpoint detection apparatus 626 may be in communication with the system controller 116 and/or other assemblies similar to the polymer endpoint detection apparatus 126. As the coherent light beam 640 impinges onto the Cu layer 606, the reflected light 642 is received by a receiver 632. The intensity of the reflected light 642 will change as the first thickness 610a of the Cu layer 606 is reduced and the titanium lining 650 is exposed. Finally, the intensity of the reflected light 642 will change again as the thickness 612 of the titanium lining 650 is removed and the polymer-based layer 608 is exposed. The endpoint detection apparatus 626 will halt the CMP process when the second thickness 610b of the Cu layer 606 is leveled with the polymer-based layer 608 at thickness 614. Although in the example copper was used as the fill metal, other metal-based materials may be used to fill the damascene structure 620. In some embodiments, a laser endpoint detection apparatus may also be used to perform reveal the endpoint detection on Cu features (e.g., RDL or bump) embedded in a polymer/EMC matrix, as shown in FIG. 5B. The power and intensity of the laser may be increased to compensate for the absorbing property of the polymer and/or reduced reflective properties of the EMC. The metallization can be the first, second, or n^{th} RDL, or Cu pillar/bump and the substrate can be standard Si or glass.

FIG. 7 depicts a cross sectional view 700 of an endpoint detection process using X-rays in a polymer or epoxy-based layer 706 in accordance with some embodiments. In some embodiments, the polymer endpoint detection apparatus 126 uses a polymer endpoint detector 128 that includes a transmitter 730 that produces X-rays 712 that penetrate into the polymer or epoxy-based layer 706 to a surface 708 and reflect back 714 to a receiver 732 producing an image of the substrate 702 including the underlying structure 704. The image of the substrate 702 may be utilized to determine a thickness 710 of the polymer or epoxy-based layer 706. X-rays have the ability to generate image contrast between epoxy (e.g., EMC) and conducting materials (e.g. Cu, Si), and the contrast image can be used to non-destructively detect a thickness of the polymer or epoxy-based layer 706, which is otherwise very challenging using standard optical methods.

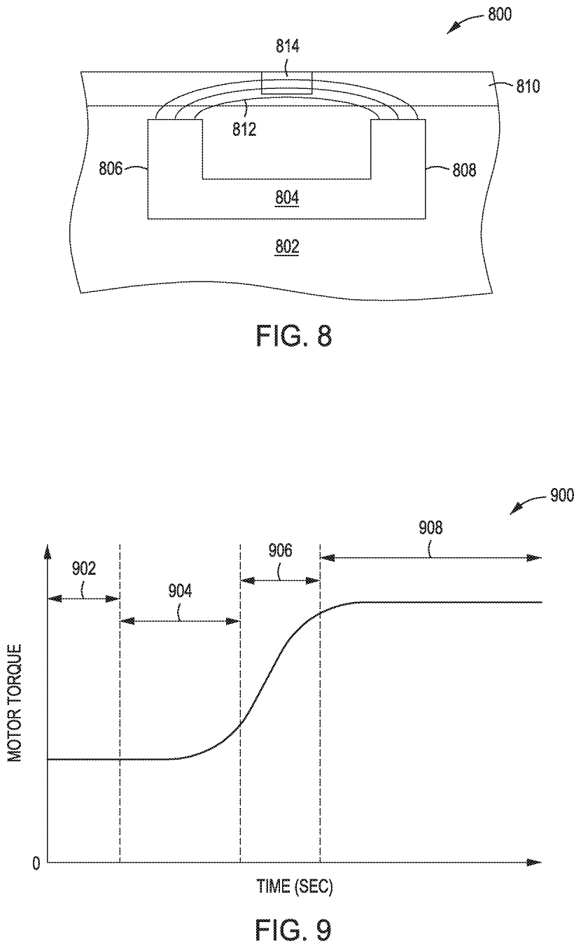

FIG. 8 depicts a cross sectional view 800 of an endpoint detection process using an eddy current 812 in a polymer-based layer 810 in accordance with some embodiments. In some embodiments, the polymer endpoint detection apparatus 126 uses a polymer endpoint detector 128 with an electromagnet 804 in a rotatable platen 802. The electromagnet 804 has a first pole 806 and a second pole 808 to induce an eddy current 812 through a metal-based material 814 in the polymer-based layer 810. The eddy currents 812 cause the metal-based material 814 in the polymer-based layer 810 to become an impedance source which changes as the amount of metal in the metal-based material 814 changes, indicating a thickness change of the metal-based material 814 and subsequently the polymer-based layer 810.

FIG. 9 depicts a graph 900 of an endpoint detection process using motor torque in accordance with some embodiments. Referring back to FIG. 1, in some embodiments, the polymer endpoint detection apparatus 126 may utilize an internal polymer endpoint detector 129 that interfaces with the platen motor 106 and/or the carrier head motor 114 to determine an endpoint for a reveal of a structure in a polymer-based layer. Due to variations in the friction of different materials such as metal and polymer, fluctuations in the torque of the platen motor 106 and/or the carrier head motor 114 may be used to determine when a metal structure has been revealed as the friction will increase when the metal structures are exposed. In a first stage 902, the CMP process begins and stabilizes. In a second stage 904, the polymer-based layer begins to thin out exposing some embedded metal material. In third stage 906, the embedded metal material is progressively exposed, increasing friction and torque. In a fourth stage period 908, the embedded metal material is fully exposed, creating the most friction and the highest torque, triggering a reveal endpoint for the CMP process. The same endpoint technique can be generalized to heterogeneous polymer material, e.g. EMC.

The inventors have found that due to the uniqueness of polymer and/or epoxy-based materials that utilizing one or more of the above described techniques may assist in better determining an endpoint for the CMP process. In some embodiments, the polymer endpoint detection apparatus 126 may use more than one of an optical detection, a motor torque detection, an eddy current detection, and an X-ray detection for various endpoint detections in CMP processes where polymer and/or epoxy-based materials are involved.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for chemical mechanical planarization (CMP) of a polymer or epoxy-based layer, comprising:
obtaining an endpoint for polymer or epoxy-based material for use in a CMP process, the CMP process configured to polish polymer or epoxy-based material;
monitoring the polymer or epoxy-based layer with an endpoint detection apparatus configured to monitor polymer or epoxy-based material;
polishing the polymer or epoxy-based layer with the CMP process;
detecting when the polymer or epoxy-based layer has reached the endpoint for the CMP process; and
halting the CMP process when the endpoint is detected.

2. The method of claim 1, further comprising:
using an optical detection apparatus as the endpoint detection apparatus, the optical detection apparatus is configured to operate at a wavelength of approximately 200 nm to approximately 1700 nm and is configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm.

3. The method of claim 1, further comprising:
using an optical detection apparatus as the endpoint detection apparatus, wherein the polymer or epoxy-based layer has at least one underlying redistribution layer or bump and the optical detection apparatus is configured to operate at a wavelength of approximately 200 nm to approximately 1700 nm and to planarize the polymer or epoxy-based layer.

4. The method of claim 1, further comprising:
obtaining the endpoint for the polymer or epoxy-based layer from a combination of stored data and monitored data.

5. The method of claim 1, further comprising:
using an optical detection apparatus as the endpoint detection apparatus, the optical detection apparatus is configured to operate at a wavelength of approximately 200 nm to approximately 1700 nm and is configured to detect a reveal of a metal-based material in the polymer or epoxy-based layer.

6. The method of claim 1, further comprising:
using a laser detection apparatus as the endpoint detection apparatus, the laser detection apparatus is configured to detect metal clearance in a polymer damascene structure in the polymer or epoxy-based layer.

7. The method of claim 1, further comprising:
using a motor torque detection apparatus as the endpoint detection apparatus, the motor torque detection apparatus is configured to detect metal reveals in the polymer or epoxy-based layer based on changes in torque applied to one or more motors of a CMP process chamber.

8. The method of claim 1, further comprising:
using an eddy current detection apparatus as the endpoint detection apparatus, the eddy current detection apparatus is configured to detect a thickness of a metal-based material in the polymer or epoxy-based layer.

9. The method of claim 1, further comprising:
using an X-ray detection apparatus as the endpoint detection apparatus, the X-ray detection apparatus is configured to non-destructively detect a thickness of the polymer or epoxy-based layer.

10. The method of claim 1, further comprising:
using more than one of an optical detection apparatus, a motor torque detection apparatus, an eddy current detection apparatus, and an X-ray detection apparatus as the endpoint detection apparatus.

11. A method for chemical mechanical planarization (CMP) of a polymer or epoxy-based layer, comprising:
obtaining an endpoint for polymer or epoxy-based material for use in a CMP process, the CMP process configured to polish polymer or epoxy-based material;
monitoring the polymer or epoxy-based layer with an optical detection apparatus configured to monitor polymer or epoxy-based material and configured to operate at a wavelength of approximately 200 nm to approximately 800 nm or a wavelength of approximately 900 nm to approximately 1700 nm;
polishing the polymer or epoxy-based layer with the CMP process;
detecting when the polymer or epoxy-based layer has reached the endpoint for the CMP process; and
halting the CMP process when the endpoint is detected.

12. The method of claim 11, wherein the optical detection apparatus is configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm.

13. The method of claim 11, wherein the polymer or epoxy-based layer has at least one underlying redistribution layer or bump and the optical detection apparatus is configured to planarize polymer or epoxy-based layer.

14. The method of claim 11, further comprising:
obtaining the endpoint for the polymer or epoxy-based layer from a combination of stored data and monitored data.

15. The method of claim 11, wherein the optical detection apparatus is configured to detect a reveal of a metal-based material in the polymer or epoxy-based layer.

16. The method of claim 11, further comprising:
using the optical detection apparatus and at least one of a motor torque detection apparatus, an eddy current detection apparatus, and an X-ray detection apparatus to detect the endpoint of the CMP process for the polymer or epoxy-based layer.

17. A non-transitory, computer readable medium having instructions stored thereon that, when executed, cause a method for chemical mechanical planarization (CMP) of a polymer or epoxy-based layer to be performed, the method comprising:
obtaining an endpoint for polymer or epoxy-based material for use in a CMP process, the CMP process configured to polish polymer or epoxy-based material;
monitoring the polymer or epoxy-based layer with an endpoint detection apparatus configured to monitor polymer or epoxy-based material;
polishing the polymer or epoxy-based layer with the CMP process;
detecting when the polymer or epoxy-based layer has reached the endpoint for the CMP process; and
halting the CMP process when the endpoint is detected.

18. The non-transitory, computer readable medium of claim 17, further comprising:
using an optical detection apparatus as the endpoint detection apparatus, the optical detection apparatus is configured to operate at a wavelength of approximately 200 nm to approximately 1700 nm and configured to reduce step height of the polymer or epoxy-based layer such that a surface of the polymer or epoxy-based layer has a uniformity that supports a redistribution layer with at least two lead outs with line and spacing of approximately greater than 0/0 μm to less than or equal to approximately 2/2 μm.

19. The non-transitory, computer readable medium of claim 17, further comprising:
using an optical detection apparatus as the endpoint detection apparatus, the optical detection apparatus is configured to operate at a wavelength of approximately 200 nm to approximately 1700 nm and configured to detect a reveal of a metal-based material in the polymer or epoxy-based layer.

20. The non-transitory, computer readable medium of claim 17, further comprising:
using more than one of an optical detection apparatus, a motor torque detection apparatus, an eddy current detection apparatus, and an X-ray detection apparatus as the endpoint detection apparatus.
